(19) United States
(12) Patent Application Publication
(10) Pub. No.: US 2011/0159445 A1
(43) Pub. Date: Jun. 30, 2011

(54) Method for Making a Texture on a Transparent Conductive Film of a Solar Cell

(75) Inventors: Chao-Nan Wei, Taoyuan County (TW); Hui-Yun Bor, Taipei (TW); Kuan-Zong Fung, Taoyuan County (TW); Yi-Chian Liao, Taoyuan County (TW)

(73) Assignee: Chung-Shan Institute of Science and Technology, Armaments, Bureau, Ministry of National Defense, Taoyuan County (TW)

(21) Appl. No.: 12/948,991

(22) Filed: Nov. 18, 2010

(30) Foreign Application Priority Data
Dec. 29, 2009 (TW) 098145446

(51) Int. Cl. G03F 7/20

(52) U.S. Cl. 430/323

(57) ABSTRACT

Disclosed is a method for making a texture on a face of a transparent conductive film coated on a glass substrate. The method includes the steps of forming a texture on the face of the glass substrate and coating the transparent conductive film on the texture formed on the face of the glass substrate.

### BACKGROUND OF INVENTION

1. Field of Invention

The present invention relates to a method for making a texture on a transparent conductive film of a solar cell.

2. Related Prior Art

As the prices of fossil fuels are rising, the need for solar cells is also rising. To promote solar energy as an environmentally friendly type of energy, it is important to reduce the cost of making solar cells. Solar cells which each include an amorphous or nano-crystalline silicon film coated on a glass substrate are promising in this regard.

It is also important to reduce the cost of generation by solar cells. To reduce the cost of generation by the solar cells, it is important to improve the efficiencies of the solar cells. The efficiencies of the solar cells can be improved in three aspects, i.e., the absorption rate, the conversion efficiency and the conduction efficiency. For a thin-film solar cell, light is not completely absorbed by an absorption layer (or “conversion layer”). A portion of the solar energy is wasted.

To improve the absorption rate, a texture is made on a layer of transparent conductive oxide coated on the absorption layer. Light is diffused when it is transmitted through the absorption layer. Thus, the light travels for a long distance in the absorption layer. This is “light trapping” for improving the absorption rate and, therefore, the efficiency of the thin-film solar cell. The degree of the diffusion is a function of a haze value, i.e., a ratio of diffused transmitted light over completely transmitted light.

Referring to FIG. 1, a first conventional solar cell includes a glass substrate 1, a first transparent conductive film 2, a conversion layer 3 and a second transparent conductive film 4. In operation, light travels into the conversion layer 3 through the glass substrate 1 and the first transparent conductive film 2. A portion of the light produces electron-hole pairs in the conversion layer 3. The other portion of the light however travels through the second transparent conductive film 4 and get lost. Therefore, the efficiency of the first conventional solar cell is low.

Referring to FIG. 2, a second conventional solar cell includes a glass substrate 1, a first transparent conductive film 2, a conversion layer 3 and a second transparent conductive film 4. A textured interface 21 is made between the first transparent conductive film 2 and the conversion layer 3. In operation, light travels into the conversion layer 3 through the glass substrate 1 and the first transparent conductive film 2. The light is diffused when it is transmitted through the textured interface 21. The direction of the travel of the light is changed. Total reflection of the light in the first transparent conductive film 2 is increased, and more of the light is reflected back into the conversion layer 3 to increase the efficiency of the second solar cell.

The present invention is therefore intended to obviate or at least alleviate the problems encountered in prior art.

### SUMMARY OF INVENTION

It is the primary objective of the present invention to provide a method for making a texture on a face of a transparent conductive film coated on a glass substrate.

To achieve the foregoing objective, the method includes the steps of forming a texture on the face of the glass substrate and coating the transparent conductive film on the texture formed on the face of the glass substrate.

Other objectives, advantages and features of the present invention will be apparent from the following description referring to the attached drawings.

### BRIEF DESCRIPTION OF DRAWINGS

The present invention will be described via detailed illustration of three embodiments in view of the prior art referring to the drawings wherein:

FIG. 1 is a cross-sectional view of a conventional solar cell;

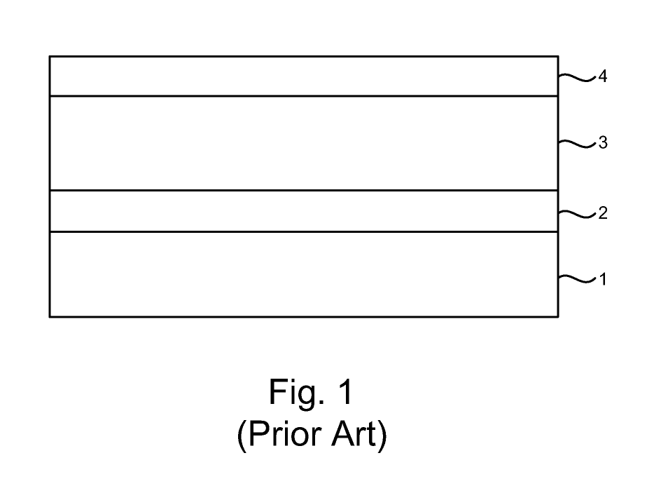

FIG. 2 is a cross-sectional view of another conventional solar cell;

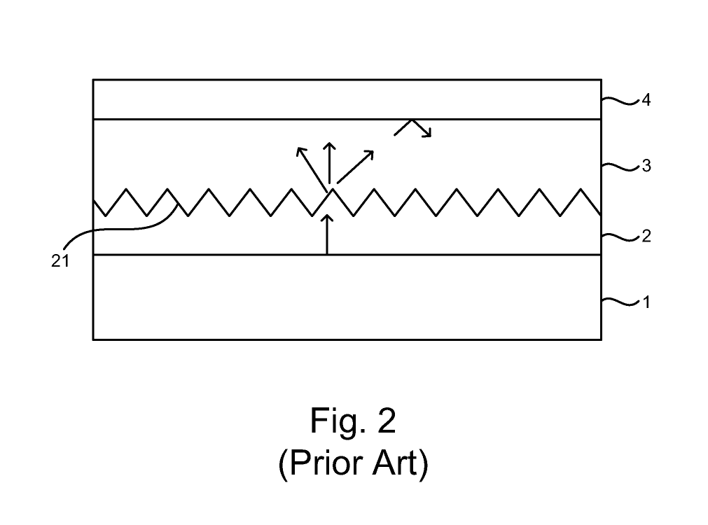

FIG. 3 is a cross-sectional view of a transparent conductive film coated on a glass substrate according to the first embodiment of the present invention;

FIG. 4 shows a method for coating the transparent conductive film on the glass panel substrate shown in FIG. 3;

FIG. 5 is a perspective view of the transparent conductive film coated on the glass substrate shown in FIG. 4;

FIG. 6 is a perspective view of a transparent conductive film coated on a glass substrate in accordance with the second embodiment of the present invention; and

FIG. 7 is a perspective view of a transparent conductive film coated on a glass substrate according to the third embodiment of the present invention.

### DETAILED DESCRIPTION OF EMBODIMENTS

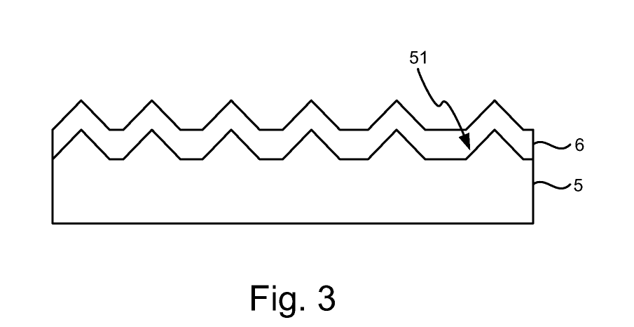

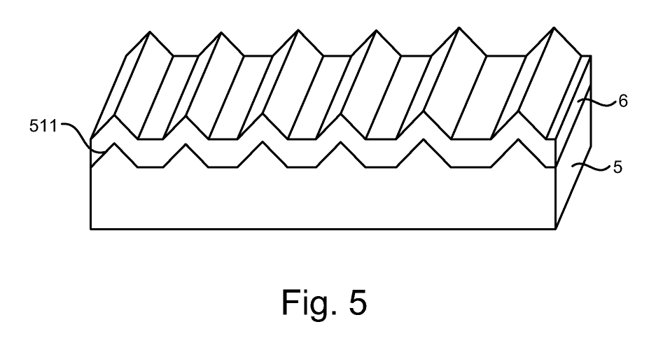

Referring to FIGS. 3 and 5, a glass substrate 5 is coated with a transparent conductive film 6 according to a first embodiment of the present invention. A texture 51 is formed on an upper face of the substrate 5. The transparent conductive film 6 is coated on the texture 51 formed on the glass substrate 5. The transparent conductive film 6 is made of a transparent conductive oxide (“TCO”) such as SnO₂, ITO or ZnO by sputtering.

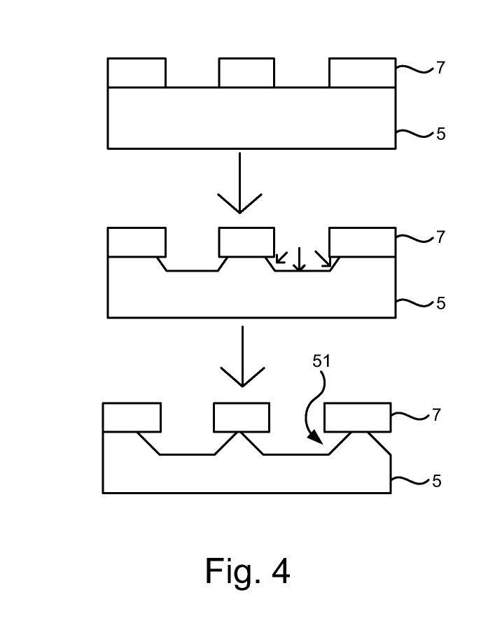

Referring to FIG. 4, the texture 51 is made by lithography-aided etching. At first, a layer of photo-resist 7 is coated on the glass substrate 5. The photo-resist 7 and the glass substrate 5 are subjected to lithography. Portions of the photo-resist 7 exposed to light are washed away. The remaining photo-resist 7 is used as an etching-resistant layer. The etching-resistant layer and the glass substrate 5 are subjected to chemical etching. Thus, the texture 51 is made on the glass substrate 5. Finally, the transparent conductive film 6 is coated on the texture 51 on the surface of the glass substrate 5.

The texture 51 on the glass substrate 5 includes parallel rectilinear ridges 511 each including a peak. The width of the ridges 511 is about 20 μm to 500 nm. The ridges 511 cover about 50% of the upper face of the glass substrate 5. The texture 51 increases the haze value by 16%.

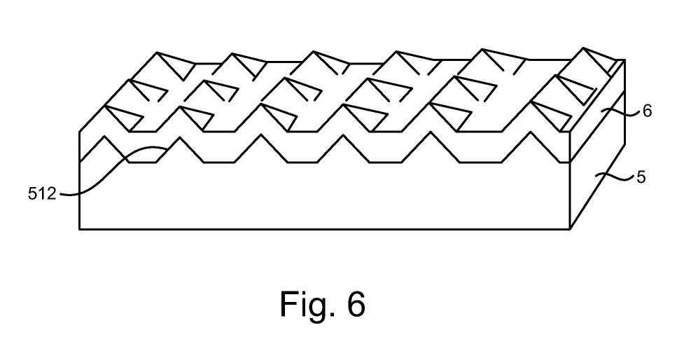

Referring to FIG. 6, there is shown a laminate according to a second embodiment of the present invention. The second embodiment is like the first embodiment except that the texture 51 includes pyramid-shaped bosses 512. The width of the pyramid-shaped bosses 512 is about 20 μm to 500 nm. The pyramid-shaped bosses 512 cover up to 69% of the upper face of the glass substrate 5. The texture 51 increases the haze value by 19%.

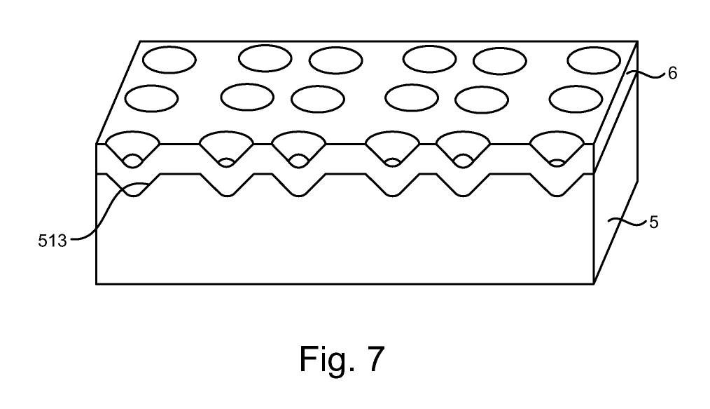

Referring to FIG. 7, there is shown a laminate according to a third embodiment of the present invention. The second embodiment is like the first embodiment except that the texture 51 includes cavities 513. The width of the cavities 513 is about 20 μm to 500 nm. The pyramid-shaped bosses 512 cover up to 84% of the upper face of the glass substrate 5. The texture 51 increases the haze value by 19%.

Advantageously, the ridges 511, the bosses 512 or the cavities 513 increase the haze value and therefore the conversion efficiency.

The present invention has been described via the detailed illustration of the embodiments. Those skilled in the art can derive variations from the embodiments without departing from the scope of the present invention. Therefore, the embodiments shall not limit the scope of the present invention defined in the claims.

1. A method for making a texture on a face of a transparent conductive film coated on a glass substrate, the method including the steps of:
forming a texture 51 on the face of the glass substrate 5; and
coating the transparent conductive film 6 on the texture 51 formed on the face of the glass substrate 5.

2. The method according to claim 1, wherein step of forming the texture 51 on the face of the glass substrate 5 includes the step of executing lithograph-aided etching on the face of the glass substrate 5.

3. The method according to claim 2, wherein the texture 51 includes parallel rectilinear ridges 511 with a width of 20 μm to 500 nm.

4. The method according to claim 2, wherein the texture 51 includes pyramid-shaped bosses 512 with a width of 20 μm to 500 nm.

5. The method according to claim 2, wherein the texture 51 includes cavities 513 with a width of 20 μm to 500 nm.

6. The method according to claim 1, wherein the transparent conductive film 6 is made of a transparent conductive oxide selected from the group consisting of SnO₂, ITO and ZnO.
